(19) United States
(12) Patent Application Publication
(10) Pub. No.: US 2015/0255536 A1
(43) Pub. Date: Sep. 10, 2015

(54) SEMICONDUCTOR DEVICE

(71) Applicant: KABUSHIKI KAISHA TOSHIBA, Tokyo (JP)

(72) Inventor: Naomasa SUGITA, Nomi Ishikawa (JP)

(21) Appl. No.: 14/475,548

(22) Filed: Sep. 2, 2014

(30) Foreign Application Priority Data
Mar. 5, 2014 (JP) 2014-043303

(51) Int. Cl. H01L 29/06; H01L 29/861

(52) U.S. Cl. CPC H01L 29/0619; H01L 29/8611

(57) ABSTRACT

A semiconductor device in an embodiment includes a first semiconductor region of a first conductivity type on a cathode electrode and a second semiconductor region of the first conductivity type between an anode electrode and the cathode electrode and in direct contact with the first semiconductor region. A first conductivity type dopant concentration of the second semiconductor region is higher than a first conductivity type dopant concentration of the first semiconductor region. A third semiconductor region of a second conductivity type is between the anode electrode and the second semiconductor region and in direct contact with the second semiconductor region. A fourth semiconductor region is in direct contact with the second semiconductor region and a portion of the third semiconductor region.

### CROSS-REFERENCE TO RELATED APPLICATION

This application is based upon and claims the benefit of priority from Japanese Patent Application No. 2014-043303, filed Mar. 5, 2014, the entire contents of which are incorporated herein by reference.

### FIELD

Embodiments described herein relate generally to a semiconductor device.

### BACKGROUND

Diodes include p-n junction diodes and constant voltage diodes using breakdown current. In general, a constant voltage diode includes a high dopant concentration region and a low dopant concentration region, and a balance at the junction between the high concentration region and the low concentration region determines a breakdown voltage. In general, a semiconductor wafer or an epitaxial layer is used as the low dopant concentration region.

Wafers are typically formed by a Czochralski (CZ) method, and wafers useful for forming a diode having a predetermined breakdown voltage corresponds to wafers from only certain parts of an ingot generated by the CZ method because, in general, a wafer formed by the CZ method may have large variation in in-plane specific resistance due to a variety of factors. Consequently, not all wafers formed by this method will have the desired breakdown voltage.

In a case of an epitaxial layer, since generally a plurality of film forming processes may be performed using different conditions in the same film forming apparatus, batch-to-batch dopant concentration control is difficult. That is, because different types of epitaxial layers may be formed in the same film forming apparatus, the stability of the epitaxial layer formation process may be poor. For this reason, there is a possibility that an epitaxial layer having a desired breakdown voltage will not be reliably obtained.

### DESCRIPTION OF THE DRAWINGS

FIG. 1 is a cross-sectional view schematically illustrating a semiconductor device according to a first embodiment.

FIGS. 2A to 2C are cross-sectional views schematically illustrating a process of manufacturing the semiconductor device according to the first embodiment.

FIGS. 3A to 3C are cross-sectional views schematically illustrating the process of manufacturing the semiconductor device according to the first embodiment.

FIG. 4A is a view schematically illustrating a cross section and dopant concentrations of a semiconductor device according to a reference example.

FIG. 4B is a view schematically illustrating a cross section and dopant concentrations of the semiconductor device according to the first embodiment.

FIG. 5 is a cross-sectional view schematically illustrating a semiconductor device according to a second embodiment.

FIG. 6 is a cross-sectional view schematically illustrating a semiconductor device according to a third embodiment.

FIG. 7 is a cross-sectional view schematically illustrating a semiconductor device according to a fourth embodiment.

FIG. 8 is a cross-sectional view schematically illustrating a semiconductor device according to a fifth embodiment.

FIG. 9 is a cross-sectional view schematically illustrating a semiconductor device according to a sixth embodiment.

FIG. 10 is a cross-sectional view schematically illustrating a semiconductor device according to a seventh embodiment.

FIGS. 11A and 11B are cross-sectional views schematically illustrating the semiconductor device according to the seventh embodiment.

### DETAILED DESCRIPTION

Embodiments provide a semiconductor device capable of suppressing a decrease in breakdown voltage.

According to an embodiment, a semiconductor device includes a first semiconductor region of a first conductivity type (e.g., n-type) on a cathode electrode and a second semiconductor region of the first conductivity type between an anode electrode and the cathode electrode. The second semiconductor region is in direct contact with the first semiconductor region. A first conductivity type dopant concentration of the second semiconductor region is higher than a first conductivity type dopant concentration of the first semiconductor region. A third semiconductor region of a second conductivity type (e.g., p-type) is between the anode electrode and the second semiconductor region. The third semiconductor region is in direct contact with the second semiconductor region. A fourth semiconductor region is in direct contact with the second semiconductor region and a portion of the third semiconductor region.

In general, according to one embodiment, a semiconductor device includes: a cathode electrode; an anode electrode; a first conductivity type first semiconductor region that is provided on the cathode electrode and below the anode electrode; a first conductivity type second semiconductor region that is provided between the anode electrode and the cathode electrode, and has a first conductivity type dopant concentration higher than a dopant concentration of the first semiconductor region, and is surrounded by the first semiconductor region; a second conductivity type third semiconductor region that is provided between the anode electrode and the second semiconductor region, whose portion other than a surface on an anode electrode side is surrounded by the second semiconductor region; and a fourth semiconductor region that is provided between the third semiconductor region and the second semiconductor region, and surrounds an end portion of the third semiconductor region.

Hereinafter, embodiments will be described with reference to the accompanying drawings. In the following description, similar elements will be denoted by the same reference symbols, and if an element is described once, the corresponding element in subsequent figures may not be described again. In the example embodiments, terms “n⁻ type”, “n type”, “n⁺ type”, and “n⁺⁺ type” material, regions, or layers maybe referred to as having a first conductivity type. Also, the concentration of active n-type dopant increases in the listed order. That is, n⁺⁺ type has a greater concentration that n⁺ type, which in turn is greater than n type, and so forth. Material, regions, or layers described by the terms “p type” and “p⁺ type” may be referred to as having a second conductivity type in the example embodiments. Also, p⁺ type material has a greater concentration of active p-type dopant than p type material.

### First Embodiment

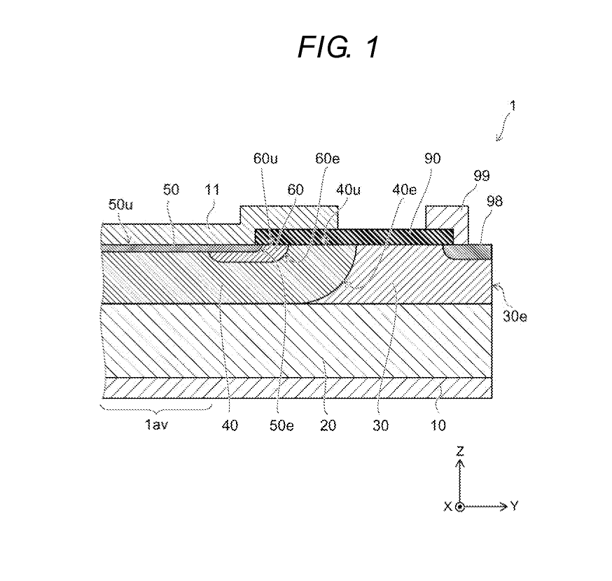

FIG. 1 is a cross-sectional view schematically illustrating a semiconductor device according to a first embodiment.

Semiconductor device 1 is a constant voltage diode having a cathode electrode 10 serving as a lower electrode, and an anode electrode 11 serving as an upper electrode.

On the cathode electrode 10, an n⁺⁺ type sixth semiconductor region 20 is provided. The sixth semiconductor region 20 is provided between a first semiconductor region 30 and the cathode electrode 10 and between a second semiconductor region 40 and the cathode electrode 10. The first semiconductor region 30 and the second semiconductor region 40 are adjacent to each other in a plane parallel to sixth semiconductor region 20 (that is, along the Y-direction of FIG. 1). The first semiconductor region 30 has at least a portion provided between, along the Z-direction of FIG. 1, the sixth semiconductor region 20 and the anode electrode 11, and is of an n⁻ type.

The second semiconductor region 40 is provided between the anode electrode 11 and the cathode electrode 10 and is of an n⁻ type. The second semiconductor region 40 contains an n type dopant element (such as phosphorous (P) or arsenic (As)) in a dopant concentration higher than the dopant concentration of the first semiconductor region 30. At least a portion of an end portion 40e of the second semiconductor region 40 is directly contacted by the first semiconductor region 30.

A p⁺ type third semiconductor region 50 is provided between the anode electrode 11 and the second semiconductor region 40. A portion of the third semiconductor region 50 other than a surface 50u is directly contacted by the second semiconductor region 40. The surface 50u is on the anode electrode side of the third semiconductor region 50 (e.g., the upper surface of region 50 in FIG. 1).

An interlayer insulating film 90 is provide on a surface the second semiconductor region 40 and the third semiconductor region 50. A p type fourth semiconductor region 60 is provided between the interlayer insulating film and the second semiconductor region 40 in the Z-direction of FIG. 1 and between the third semiconductor region 50 and the second semiconductor region 40 in the Z-direction of FIG. 1. In this embodiment, the fourth semiconductor region 60 is provided in direct contact with at least an end portion 50e of the third semiconductor region 50. That is, the end portion 50e of the third semiconductor region 50 is directly contacted by the fourth semiconductor region 60, and an end portion 60e of the fourth semiconductor region 60 is directly contacted by the second semiconductor region 40. The end portion 40e of the second semiconductor region 40 is directly contacted by the first semiconductor region 30.

The interlayer insulating film 90 is provided on the first semiconductor region. Also, in an end portion 30e of the first semiconductor region 30, an equivalent potential ring (EQPR region) 98 may be provided. On the EQPR region 98, an EQPR electrode 99 may be provided. The EQPR region 98 and the EQPR electrode 99 are optional elements in some embodiments.

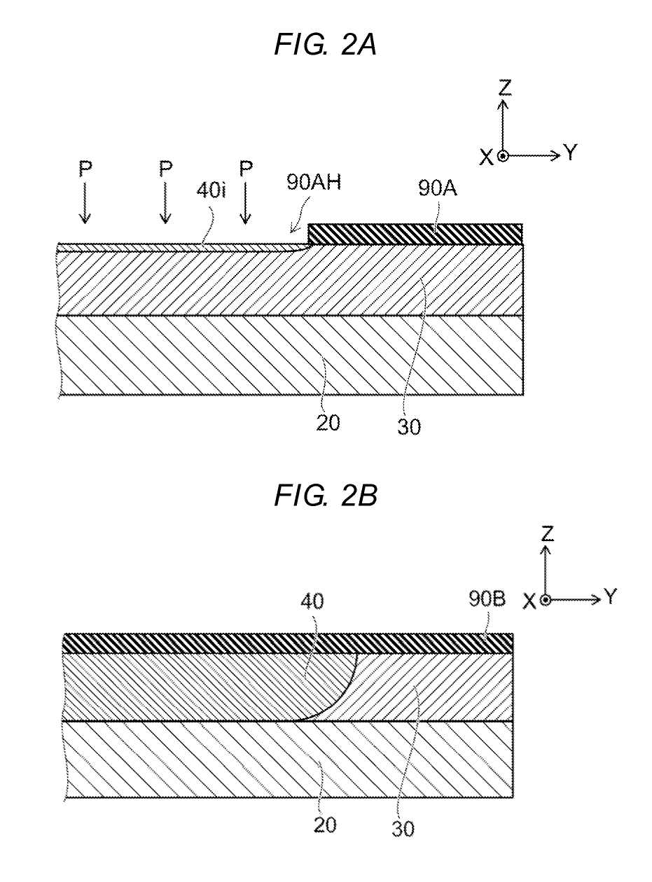

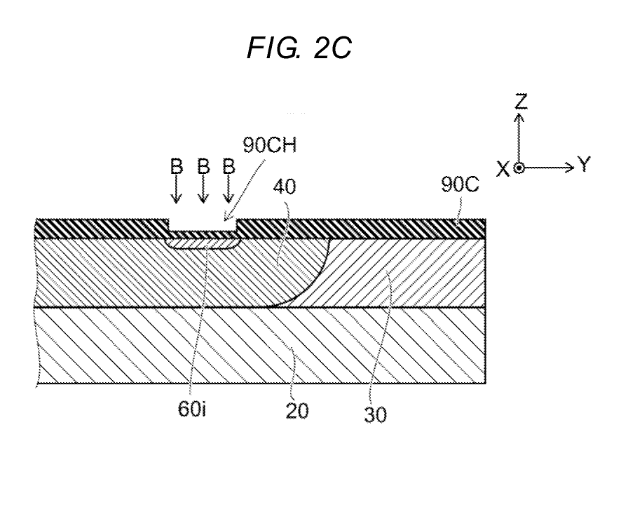

FIGS. 2A to 3C are cross-sectional views schematically illustrating a process of manufacturing the semiconductor device according to the first embodiment.

Hereinafter, a constant voltage diode having a voltage of 30 V to 40 V will be described as an example. The constant voltage value of 30 V to 40 V and numerical values to be shown below are examples, and the present disclosure is not limited to those values. Also, in FIGS. 2A to 3C, the EQPR region 98 and the EQPR electrode 99 are not illustrated but may be incorporated in some embodiments.

First, as illustrated in FIG. 2A, on the sixth semiconductor region 20 (which, in this example, is a semiconductor wafer or a portion thereof) the first semiconductor region 30 is formed. The sixth semiconductor region 20 is here a semiconductor wafer substrate having a crystal orientation (100) and specific resistance of 0.003 (Ω·cm). The sixth semiconductor region 20 is doped with arsenic (As), for example.

The first semiconductor region 30 is an epitaxial layer formed on the sixth semiconductor region 20. The first semiconductor region 30 is doped with phosphorous (P) and has specific resistance of 1.7 (Ω·cm), for example. The thickness of the first semiconductor region 30 is 10 μm, as an example.

An insulating film 90A is patterned on the first semiconductor region 30. The insulating film 90A is provided with an opening 90AH. The thickness of the insulating film 90A is 0.8 μm, as an example.

Subsequently, ion implantation is performed, whereby dopant ions are implanted into the first semiconductor region 30 through the opening 90AH. The dopant ions are, for example, phosphorous (P) ions, the ion implantation is performed with an acceleration voltage of 100 KeV, and a dose of 1×10¹³ ions/cm² to 1×10¹⁴ ions/cm² is provided. As a result, dopant ions are implanted into the surface of the first semiconductor region 30 that is exposed through the opening 90AH, whereby a region 40i is formed. Thereafter, the insulating film 90A can be removed.

Next, the region 40i and the first semiconductor region 30 are covered with an insulating film 90B. Thereafter, an annealing process is performed on the first semiconductor region 30 as illustrated in FIG. 2B. As a result, the dopant ions from the region 40i diffuse, whereby the second semiconductor region 40 is formed on the sixth semiconductor region 20. Insulating film 90B can be removed or patterned for subsequent processing steps.

Next, as illustrated in FIG. 2C, an insulating film 90C is formed on the first semiconductor region 30 and the second semiconductor region 40 such that the insulating film 90C has a region 90CH which is a potion selectively formed to be thinner. The region 90CH is a portion selectively formed in the insulating film 90C so as to be thinner than the bulk of insulating film 90C. The thickness of the region 90CH is about 100 nm, for example, and insulating film 90C has a thickness is 0.8 μm, for example.

Subsequently, ion implantation is performed, whereby dopant ions (for example, boron (B) ions) are implemented into the second semiconductor region 40 through the region 90CH. The ion implantation is performed with an acceleration voltage of 100 KeV and a dose of 1×10¹⁵ ions/cm². As a result, dopant ions are implanted into the surface of the second semiconductor region 40 via the region 90CH, whereby a region 60i is formed.

Subsequently, as illustrated in FIG. 3A, an annealing process is performed. As a result, the dopant ions of the region 60i diffuse, whereby the fourth semiconductor region 60 is formed on the second semiconductor region 40. Also, before the annealing process, an insulating film may be additionally formed on the region 90CH, if necessary.

Next, as illustrated in FIG. 3B, an insulating film 90D is formed on the first semiconductor region 30, the second semiconductor region 40, and the fourth semiconductor region 60 such that the insulating film 90D has a region 90DH which is a portion selectively formed to be thinner than the bulk of insulating film 90D. The region 90DH is formed on at least a portion of the second semiconductor region 40 and at least a portion of the fourth semiconductor region 60. The thickness of the region 90DH is about 100 nm, for example, and insulating film 90D has a thickness is 0.8 μm, for example.

Subsequently, ion implantation is performed, whereby dopant ions (for example, boron (B) ions) are implanted into the second semiconductor region 40 and the fourth semiconductor region 60 through the region 90DH. The ion implantation is performed with an acceleration voltage of 100 KeV and a dose of 1×10¹⁵ ions/cm². As a result, dopant ions are implanted into the portion(s) of the second semiconductor region 40 and the portion(s) the fourth semiconductor region 60 which are below the region 90DH, whereby a region 50i is formed. Generally, the region 50i will be formed proximate to an upper (as depicted in FIG. 3B) surface of the second semiconductor region 40 and an upper (as depicted in FIG. 3B) surface of the fourth semiconductor region 60.

Subsequently, as illustrated in FIG. 3C, an annealing process is performed. As a result, the dopant ions of the region 50i diffuse, whereby the third semiconductor region 50 is formed on the second semiconductor region 40 and the fourth semiconductor region 60. Also, before the annealing process, an insulating film may be additionally formed on the region 90DH.

Thereafter, a portion of the insulating film 90D on the surface 50u of the third semiconductor region 50 is removed, whereby the interlayer insulating film 90 is formed, as illustrated in FIG. 1. The anode electrode 11 is then formed. The anode electrode 11 in this embodiment has a laminate structure comprising a barrier metal layer and an aluminum electrode layer. The barrier metal layer is formed below the aluminum electrode layer in order to prevent diffusion/migration of aluminum atoms into the semiconductor regions. Further, on the anode electrode 11, an auxiliary electrode layer, for example, a layer capable of being brazed or soldered, such as nickel (Ni) or cobalt (Co) layer, may be formed to allow external electrical connections to be made to the anode electrode 11. Next, patterning may be performed on the anode electrode 11, and a passivation layer maybe formed on end portions of the anode electrode 11, if desired.

Meanwhile, on the cathode side, the rear surface of the sixth semiconductor region 20 is polished such that the sixth semiconductor region 20 has a predetermined thickness. Thereafter, on the rear surface side of the sixth semiconductor region 20, a titanium (Ti) layer, a nickel (Ni) layer, and a gold (Au) layer are sequentially formed to form a cathode electrode 10.

The semiconductor device 1 formed by the above-described manufacturing process is a constant voltage diode. As diodes, there are not only constant voltage diodes but also general p-n junction diodes may be formed. In general, a general p-n junction diode allows a current to flow in a forward direction (from the p side to the n side) and blocks a current in the reverse direction (from the n side to the p side) as long as the reverse bias voltage does not exceed a breakdown voltage level.

In this context, a region of the device in which a current flows is referred to as an operation region, and a region of the device in which a current does not flow is referred to as a non-operation region. In a constant voltage diode in a non-operation region, a device breakdown voltage is predetermined, and the non-operation region is designed to have a breakdown voltage equal to or higher than a required breakdown voltage.

The constant voltage diode relies on a breakdown current in an operation region. In general, this structure is configured by double breakdown design, and a first breakdown level is set in the operation region. Therefore, the first breakdown level is set such that a constant voltage (predetermined voltage) is obtained within the range in which the breakdown current flows. In order to obtain a stable first breakdown voltage, a second breakdown voltage is set such that the non-operation region has a breakdown voltage equal to or higher than the breakdown voltage of the operation region.

The junction breakdown voltage of the p-n junction included as a part of the constant voltage diode is determined by the operation region and the non-operation region formed around the operation region. If the junction breakdown voltage of the operation region is set to be lower than the junction breakdown voltage of the non-operation region, it is possible to allow a breakdown current to flow at the predetermined voltage. The p-n junction influencing the characteristics of the operation region is formed by junction of a high concentration dopant region and a low concentration dopant region having the opposite conductivity type of the high concentration region.

In a case of the semiconductor device 1 according to the first embodiment, the p-n junction influencing the characteristics of the operation region of the constant voltage diode is formed, for example, by the junction between the third semiconductor region 50 and the second semiconductor region 40. Also, in the vicinity of the end portion 50e of the third semiconductor region 50 influencing the operation region, a guard ring region (for example, the fourth semiconductor region 60) is formed to be partially deeper. Here, the fourth semiconductor region 60 functions as the non-operation region having a breakdown voltage higher than that of the operation region.

In this case, in the relation among a junction breakdown voltage V₂₃ between the second semiconductor region 40 and the third semiconductor region 50, a junction breakdown voltage V₂ₑ₁ between the end portion 40e of the second semiconductor region 40 and the first semiconductor region 30, a junction breakdown voltage V₃ₑ₄ between the end portion 50e of the third semiconductor region 50 and the fourth semiconductor region 60, and a j unction breakdown voltage V₄ₑ₂ between the end portion 60e of the fourth semiconductor region 60 and the second semiconductor region 40, the junction breakdown voltage V₂ₑ₁ is adjusted to be the lowest.

If a potential higher than that for the anode electrode 11 is applied to the cathode electrode 10 (a reverse bias) such that a voltage between the cathode electrode 10 and the anode electrode 11 exceeds the breakdown voltage, so-called avalanche breakdown occurs. Due to the above-described relation among the junction breakdown voltages, a current flows preferentially in the junction portion of the third semiconductor region 50 and the second semiconductor region 40. Here, the junction portion is a region 1av in which the third semiconductor region 50 and the second semiconductor region 40 meet. As depicted in FIG. 1, the junction portion between the third semiconductor region 50 and second semiconductor region 40 is planar.

In the semiconductor device 1, in order to obtain a predetermined breakdown voltage, a balance at the junction of the third semiconductor region 50 and the second semiconductor region 40 is required. In the process of manufacturing the semiconductor device 1, only a part of a non-treated wafer or an epitaxial wafer is used is used as second semiconductor region 40. Furthermore, the second semiconductor region 40 is formed by doping a portion of first semiconductor region 30 formed in sixth semiconductor region 20. Therefore, it is possible to balance the junction between the third semiconductor region 50 and the second semiconductor region 40 by adjusting the doping levels used to generate either (or both) of these regions. Now, a reference example demonstrating the use of a non-treated wafer or an epitaxial wafer as a second semiconductor region 300 will be described.

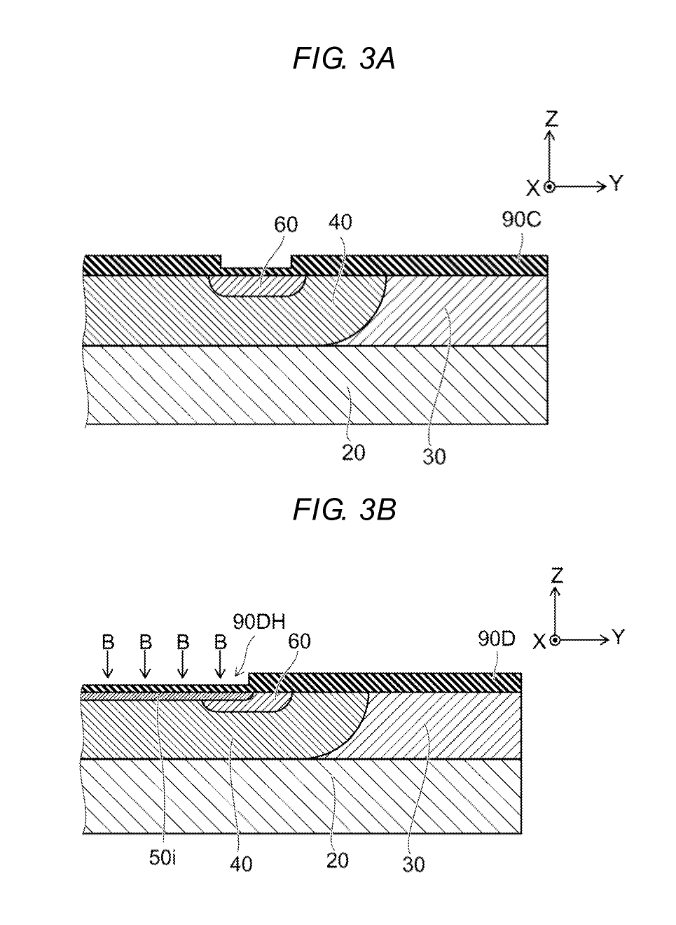

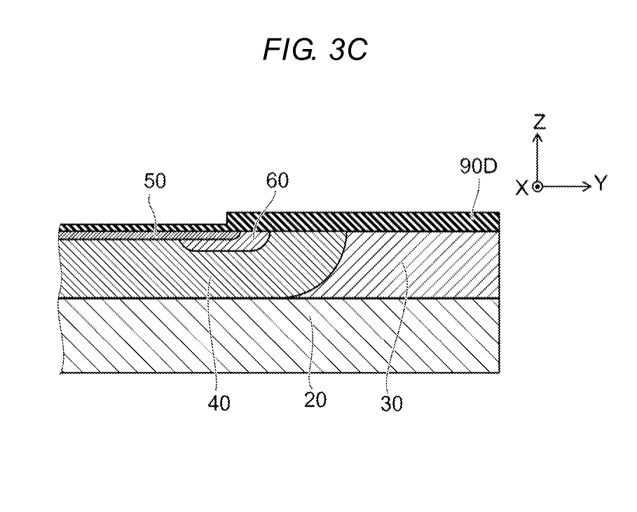

FIG. 4A is a view schematically illustrating a cross section and dopant concentrations of a semiconductor device according to a reference example, and FIG. 4B is a view schematically illustrating a cross section and dopant concentrations of the semiconductor device according to the first embodiment.

FIGS. 4A and 4B show dopant concentration profiles at cross sections along lines A-B.

In a semiconductor device 100 illustrated in FIG. 4A, a semiconductor region 300 corresponding in some respects to the above-described second semiconductor region 40 is a non-treated wafer substrate or an n⁺ type epitaxial layer.

In a case of using a non-treated wafer substrate as the semiconductor region 300, it is necessary to use a non-treated wafer having a specific resistance carefully selected to match the device breakdown voltage requirements, and perform a high concentration diffusion in an operation region according to a non-treated wafer substrate.

In general, a non-treated wafer is obtained by drawing up an ingot by the CZ method and then cutting the ingot into wafers. However, a non-treated wafer having a predetermined constant voltage may correspond to only a fraction of a drawn-up ingot due to process variations. For this reason, if a non-treated wafer substrate having a predetermined constant voltage is used as the semiconductor region 300, the price becomes high as only certain wafers from an ingot will have the predetermined characteristics required.

Also, a wafer manufactured by the CZ method may have large variation in in-plane specific resistance. This variation generally increases as the wafer diameter increases. That is, it may become impossible to obtain a predetermined constant voltage, and possible remaining improvements in the manufacturing yield are limited. Also, since the dopant concentration of a usable wafer must vary in accordance with a predetermined constant voltage (see arrows of the semiconductor region 300 of FIG. 4A), it is necessary to prepare a wafer according to each predetermined constant voltage of a desired diode device.

Meanwhile, in a case of using an epitaxial layer as the semiconductor region 300, in a constant voltage diode, epitaxial growth is generally performed at higher concentrations, as compared to the dopant concentration of a general epitaxial layer. For this reason, inside the manufacturing apparatus, a film containing a dopant element at high concentration may be formed. For this reason, when a wafer layer is manufactured according to another specification, it is necessary to perform cleaning on the inside of the manufacturing apparatus before attempting manufacturing to a different specification. Also, even if an epitaxial layer is used, it is necessary to carefully select for specific resistance, and in a case where a C-V (capacitance-voltage) measurement method is used as a quality checking method, errors become large. That is, since a special quality checking method is necessary, the price of forming the epitaxial layer and confirming its quality becomes high.

In contrast to this, according to the semiconductor device 1 illustrated in FIG. 4B, since it is possible to adjust the dopant concentration of all portions of the device, it is unnecessary to carefully select specific resistance of the raw wafer or epitaxial layer. Also, even if there is variation in specific resistance, variation in dopant concentration, or in-plane variations in the specific resistance and the dopant concentration in the first semiconductor region 30 and/or the second semiconductor region 40 it is possible to correct such variations, and form a semiconductor region having desired specific resistance and desired dopant concentration.

As described above, according to the first embodiment, it is unnecessary to determine or control the specification of a wafer for each predetermined constant voltage device, and it is possible to use a general undoped wafer or a wafer which includes an epitaxial layer to manufacture an inexpensive high-quality semiconductor device. For example, the second semiconductor region 40 is formed by ion implantation, thereby suppressing variation in the in-plane dopant concentration of the wafer or initial epitaxial layer. Therefore, it is possible to improve the manufacturing yield and manufacture a semiconductor device having small variation in breakdown voltage.

Also, the dopant concentration of the junction portion between the third semiconductor region 50 and the semiconductor region 300 in the semiconductor device 100 is intended to be substantially the same as the dopant concentration of the junction portion between the third semiconductor region 50 and the second semiconductor region 40 in the semiconductor device 1.

The dopant concentration of the first semiconductor region 30 in the semiconductor device 1 is set to be 1/10 or less of the dopant concentration of the junction portion of the third semiconductor region 50 and the semiconductor region 300 in the semiconductor device 100, more preferably, to about 1/100.

Since the dopant concentration of the first semiconductor region 30 is set to be low as described above, variation in the dopant concentration of the first semiconductor region 30 is reduced, and thereafter it is possible to perform ion implantation, thereby adjusting the dopant concentration with a high degree of accuracy.

Hereinafter, modifications of the first embodiment will be described. Semiconductor devices to be described below also have the same effects as those of the semiconductor device 1.

### Second Embodiment

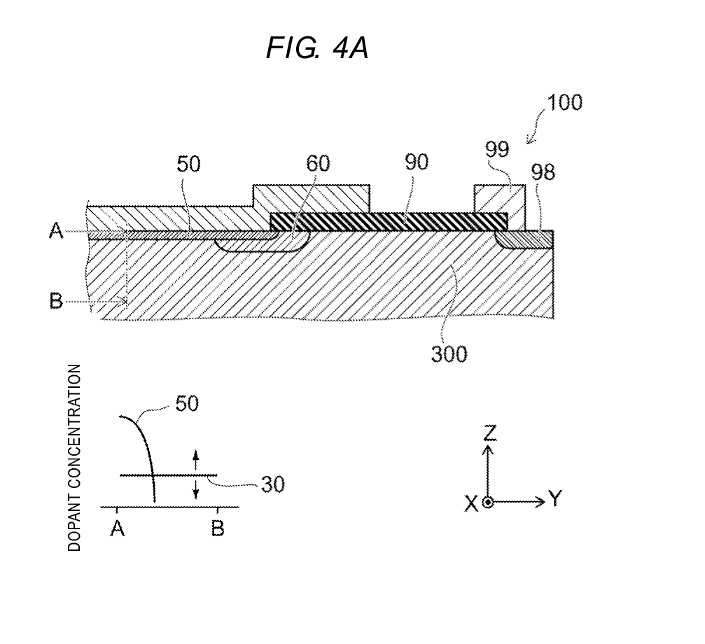

FIG. 5 is a cross-sectional view schematically illustrating a semiconductor device according to a second embodiment.

In a semiconductor device 2, the third semiconductor region 50 is provided between the anode electrode 11 and the first semiconductor region 30 and between the anode electrode 11 and the second semiconductor region 40. That is, a portion of the third semiconductor region 50 extends beyond (e.g., along the Y-direction as depicted FIG. 5) the second semiconductor region 40.

In this embodiment, in the relation among the junction breakdown voltage V₂₃ between the second semiconductor region 40 and the third semiconductor region 50, a second junction breakdown voltage V₂ₑ₃ between the end portion 40e of the second semiconductor region 40 and the third semiconductor region 50, and a third junction breakdown voltage V₂ₑ₃ between the end portion 50e of the third semiconductor region 50 and the first semiconductor region 30, the junction breakdown voltage V₂₃ is set to be lower than the second junction breakdown voltage V₂ₑ₃ and the third junction breakdown voltage V₂ₑ₃.

Therefore, if a voltage larger than the breakdown voltage is applied between the cathode electrode 10 and the anode electrode 11, a current flows preferentially in the junction portion of the third semiconductor region 50 and the second semiconductor region 40 due to avalanche breakdown.

### Third Embodiment

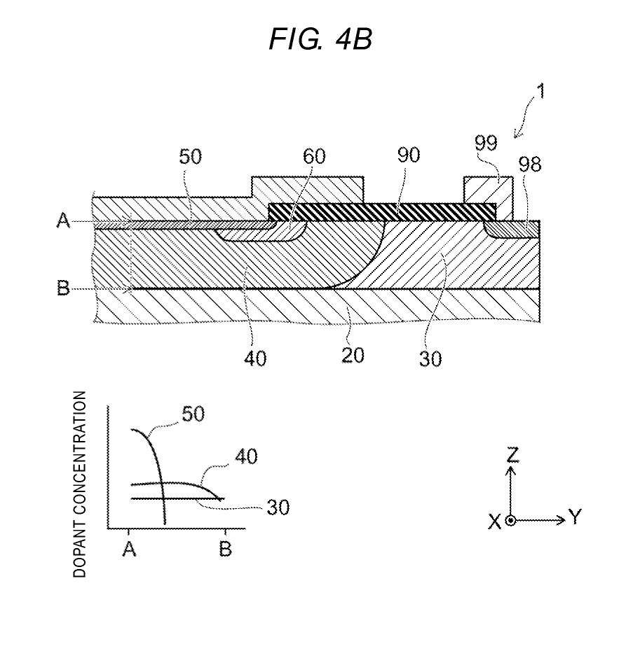

FIG. 6 is a cross-sectional view schematically illustrating a semiconductor device according to a third embodiment.

In a semiconductor device 3, the end portion 50e of the third semiconductor region 50 is directly contacted by the fourth semiconductor region 60 and a portion of the fourth semiconductor region 60 is directly contacted by the first semiconductor region 30.

In the semiconductor device 3, since the end portion 50e of the third semiconductor region 50 is surrounded by the fourth semiconductor region 60, the breakdown voltage at the end portion 50e of the third semiconductor region 50 becomes higher, as compared to the semiconductor device 2.

### Fourth Embodiment

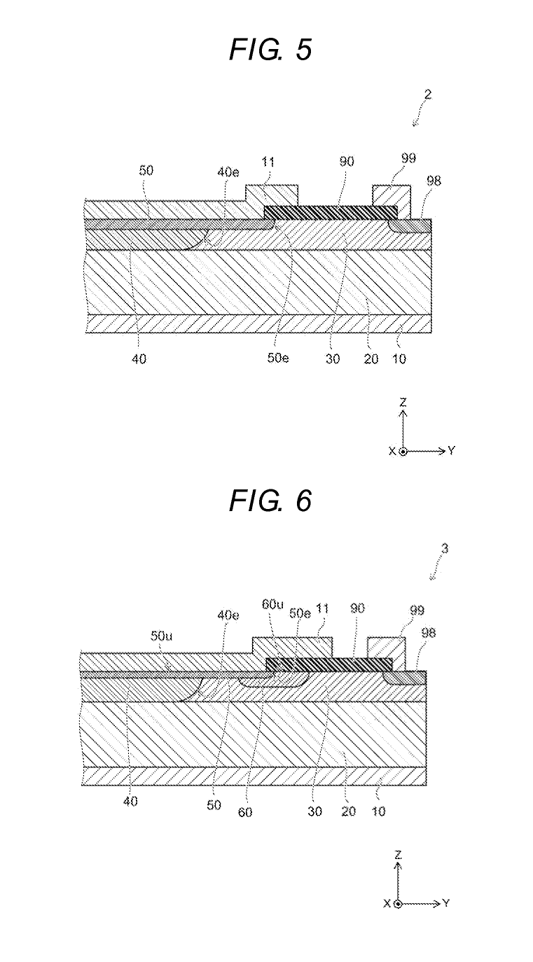

FIG. 7 is a cross-sectional view schematically illustrating a semiconductor device according to a fourth embodiment.

In a semiconductor device 4, the fourth semiconductor region 60 is in contact with the second semiconductor region and the third semiconductor region 50. The second semiconductor region 40 is formed to be deeper (along the Z-direction as depicted in FIG. 7) than the fourth semiconductor region 60. The fourth semiconductor region 60 is formed to be deeper (along the Z-direction as depicted in FIG. 7) than the third semiconductor region 50.

In this case, the junction breakdown voltage V₂₃ between the second semiconductor region 40 and the third semiconductor region 50 is set to be lower than the junction breakdown voltage V₂ₑ₄ between the end portion 40e of the second semiconductor region 40 and the fourth semiconductor region 60.

Therefore, if a voltage larger than the breakdown voltage is applied between the cathode electrode 10 and the anode electrode 11, a current flows preferentially in the junction portion of the third semiconductor region 50 and the second semiconductor region 40 due to avalanche breakdown.

### Fifth Embodiment

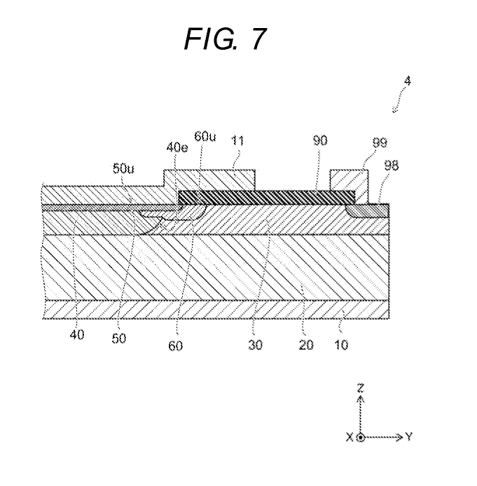

FIG. 8 is a cross-sectional view schematically illustrating a semiconductor device according to a fifth embodiment.

A semiconductor device 5 further includes a p type fifth semiconductor region 70. The fifth semiconductor region 70 directly contacts the end portion 60e of the fourth semiconductor region 60 other than its surface 60u. A portion of the fifth semiconductor region 70 other than its surface 70u is directly contacted by the first semiconductor region 30.

In this case, the dopant concentration at the surface 70u of the fifth semiconductor region 70 on the anode electrode 11 side is set to be lower than the dopant concentration of the surface 60u of the fourth semiconductor region 60 on the anode electrode 11 side. Therefore, the breakdown voltage of the end portion 60e of the fourth semiconductor region 60 becomes higher as compared to the semiconductor device 4.

### Sixth Embodiment

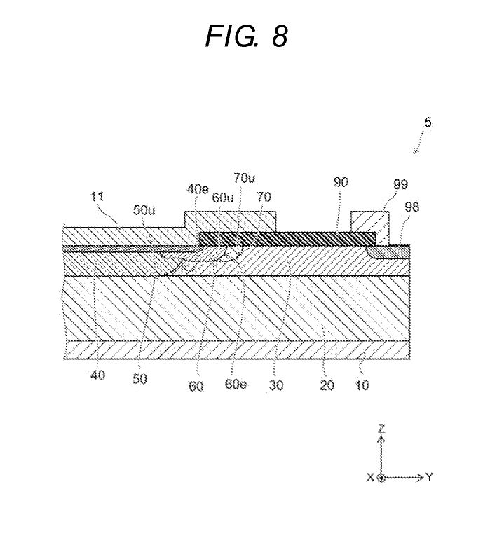

FIG. 9 is a cross-sectional view schematically illustrating a semiconductor device according to a sixth embodiment.

In a semiconductor device 6, the fourth semiconductor region 60 is formed to be deeper (along the Z-direction as depicted in FIG. 9) than the second semiconductor region 40. The second semiconductor region 40 is not in direct contact with the sixth semiconductor region 20, but rather first semiconductor region 30 is between the second semiconductor region 40 and the sixth semiconductor region 20. In this case, the dopant concentration of the surface of the second semiconductor region 40 on the anode electrode 11 side is set to be lower than the dopant concentration of the surface of the fourth semiconductor region 60 on the anode electrode 11 side.

### Seventh Embodiment

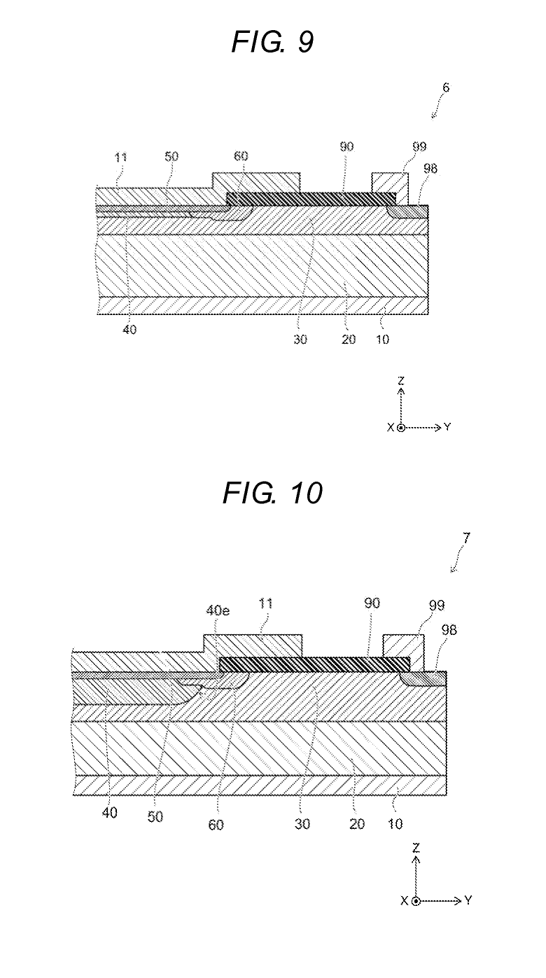

FIG. 10 is a cross-sectional view schematically illustrating a semiconductor device according to a seventh embodiment.

In a semiconductor device 7, the fourth semiconductor region 60 is in contact with the second semiconductor region and the third semiconductor region 50. The second semiconductor region 40 is formed to be deeper (along the Z-direction as depicted in FIG. 10) than the fourth semiconductor region 60. The fourth semiconductor region 60 is formed to be deeper (along the Z-direction as depicted in FIG. 10) than the third semiconductor region 50. However, in the semiconductor device 7, the second semiconductor region 40 and the sixth semiconductor region 20 are apart from each other. Between the second semiconductor region 40 and the sixth semiconductor region 20, the first semiconductor region 30 is positioned.

In this case, the junction breakdown voltage V₂₃ is set to be lower than the junction breakdown voltage V₂ₑ₄ between the end portion 40e of the second semiconductor region 40 and the fourth semiconductor region 60.

Therefore, if a voltage larger than the breakdown voltage is applied between the cathode electrode 10 and the anode electrode 11, due to avalanche breakdown, a current flows preferentially in the junction portion of the third semiconductor region 50 and the second semiconductor region 40.

Also, the structure in which the second semiconductor region 40 and the sixth semiconductor region 20 are apart from each other may be combined with the semiconductor devices 1, 2, 3, 5, and 6.

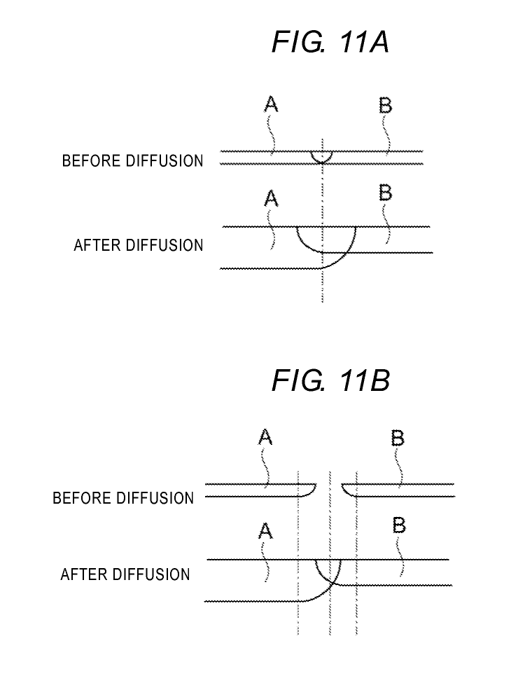

FIGS. 11A and 11B are cross-sectional views schematically illustrating the semiconductor device 7 according to the seventh embodiment.

In a case where two adjoining semiconductor regions of the semiconductor regions 30, 40, 50, 60, and 70 described above are referred to as semiconductor regions “A” and “B”, in case of the semiconductor regions “A” and “B”, diffusion sources before an annealing process may overlap, and the annealing process may cause the semiconductor regions “A” and “B” to overlap each other (FIG. 11A).

Also, in case of the adjoining semiconductor regions “A” and “B”, the diffusion sources before the annealing process may be apart from each other, and the annealing process may cause the semiconductor regions “A” and “B” to overlap each other (FIG. 11B). Annealing on the semiconductor regions “A” and “B” illustrated in each of FIG. 11A or 11B is performed at the same time.

Also, the materials of the semiconductor regions according to the example embodiments are silicon (Si) but other materials may be adopted. The materials of the insulating films are, for example, silicon oxide (SiO₂). However, these materials are just examples, and the present invention is not limited to them.

In the above-described embodiments, in a case where a portion “A” has been referred to as being on a portion “B”, the portion “A” may be directly on the portion “B”, or may be above the portion “B”. Also, in the case where the portion “A” has been referred to as being on the portion “B”, the portion “A” may be directly below the portion “B”, or the portion “A” and the portion “B” may be being side by side. This is because even if the semiconductor devices according to the embodiments are rotated, before and after the rotation, the structures of the semiconductor devices do not vary.

The embodiments have been described above with reference to specific examples. However, the embodiments are not limited to those specific examples. That is, those skilled in the art may appropriately modify the designs of those specific examples, and such modifications are also included in the scope of the embodiments as long as the modifications have the features of the embodiments. Each element of the above-described each specific example, and the disposition, material, condition, shape, size, and the like of the corresponding element are not limited to those having been illustrated, but may be appropriately changed.

In addition, the individual elements included in the embodiments described above may be combined as long as it is technically possible, and a combination thereof is included in the scope of the embodiments, as long as it has the features of the embodiments. Furthermore, in the scope of the concepts of the embodiments, a variety of variations and modifications may be considered by those skilled in the art, and it is understood that such variations and modifications belong to the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor region of a first conductivity type on a cathode electrode;
a second semiconductor region of the first conductivity type between an anode electrode and the cathode electrode, the second semiconductor region being in direct contact with the first semiconductor region, a first conductivity type dopant concentration of the second semiconductor region being higher than a first conductivity type dopant concentration of the first semiconductor region;
a third semiconductor region of a second conductivity type between the anode electrode and the second semiconductor region, the third semiconductor region being in direct contact with the second semiconductor region; and
a fourth semiconductor region in direct contact with the second semiconductor region and a portion of the third semiconductor region.

2. The semiconductor device according to claim 1, further comprising:
an equivalent potential ring region in the first semiconductor region; and
an equivalent potential ring electrode contacting the equivalent potential ring region.

3. The semiconductor device according to claim 1, further comprising:
a sixth semiconductor region of the first conductivity type between the first semiconductor region and the cathode electrode, and between the second semiconductor region and the cathode electrode, wherein
the second semiconductor region is in direct contact with the sixth semiconductor region.

4. The semiconductor device according to claim 1, further comprising:
a sixth semiconductor region of the first conductivity type between the first semiconductor region and the cathode electrode, and between the second semiconductor region and the cathode electrode, wherein
the first semiconductor region is between the second semiconductor region and the sixth semiconductor region such that second semiconductor region and the sixth semiconductor region are not in direct contact with each other.

5. The semiconductor device according to claim 4, wherein the fourth semiconductor region extends closer to the cathode electrode than does the second semiconductor region.

6. The semiconductor device according to claim 1, further comprising:
a fifth semiconductor region of the second conductivity type being in direct contact with the first semiconductor region and an end portion of the fourth semiconductor region and, wherein
a surface of the fifth semiconductor region on an anode electrode side has a dopant concentration that is lower than a dopant concentration of a surface of the fourth semiconductor region on the anode electrode side.

7. The semiconductor device according to claim 1, wherein a portion of the fourth semiconductor region is between a portion of the third semiconductor region and a portion of the second semiconductor region.

8. The semiconductor device according to claim 1, wherein the third semiconductor region and the first semiconductor region are in direct contact with each other.

9. The semiconductor device according to claim 1, wherein a first junction breakdown voltage between the second semiconductor region and the first semiconductor region is lower than a second junction breakdown voltage between the second semiconductor region and the third semiconductor region, a third junction breakdown voltage between third semiconductor region and the fourth semiconductor, and a fourth junction breakdown voltage between the second semiconductor region and the fourth semiconductor region.

10. A semiconductor device, comprising:
a first conductivity type first semiconductor region on a cathode electrode;
a second semiconductor region of a first conductivity type between an anode electrode and the cathode electrode, the second semiconductor region directly contacting the first semiconductor region, a first conductivity type dopant concentration of the second semiconductor region being higher than a first conductivity type dopant concentration of the first semiconductor region; and
a third semiconductor region of a second conductivity type between the anode electrode and the second semiconductor region, the third semiconductor region having a first portion directly contacting the first semiconductor region and a second portion directly contacting the second semiconductor region, wherein
a first junction breakdown voltage between the second semiconductor region and the third semiconductor region is lower than a second junction breakdown voltage between the second semiconductor region and the third semiconductor region and a third junction breakdown voltage between the third semiconductor region and the first semiconductor region.

11. The semiconductor device according to claim 10, further comprising:
a fourth semiconductor region of the second conductivity type being between an end portion of the third semiconductor region and the first semiconductor region.

12. The semiconductor device according to claim 11, wherein
the second semiconductor region extends closer to the cathode electrode than does the fourth semiconductor region, and
the fourth semiconductor region extends closer to the cathode electrode than does the third semiconductor region.

13. The semiconductor device according to claim 11, wherein the fourth semiconductor region extends closer to the cathode electrode than does the second semiconductor region.

14. The semiconductor device according to claim 11, further comprising:
a fifth semiconductor region of the second conductivity type that directly contacts the first semiconductor region and an end portion of the fourth semiconductor region, wherein
a surface of the fifth semiconductor region on an anode electrode side has a dopant concentration that is lower than a dopant concentration of a surface of the fourth semiconductor region on the anode electrode side.

15. The semiconductor device according to claim 10, further comprising:
a sixth semiconductor region of the first conductivity type between the first semiconductor region and the cathode electrode, and between the second semiconductor region and the cathode electrode, wherein
the second semiconductor region is in direct contact with the sixth semiconductor region.

16. The semiconductor device according to claim 10, further comprising:
a sixth semiconductor region of the first conductivity type between the first semiconductor region and the cathode electrode, and between the second semiconductor region and the cathode electrode, wherein
the first semiconductor region is between the second semiconductor region and the sixth semiconductor region such that second semiconductor region and the sixth semiconductor region are not in direct contact with each other.

17. A semiconductor device, comprising:
a first semiconductor region of a first conductivity type above, in a first direction, a cathode electrode, the first direction orthogonal to a plane of the cathode electrode;
a second semiconductor region of the first conductivity type between, in the first direction, an anode electrode and the cathode electrode, the second semiconductor region being directly adjacent to with the first semiconductor region in at least a second direction perpendicular to the first direction, a first conductivity type dopant concentration of the second semiconductor region being higher than a first conductivity type dopant concentration of the first semiconductor region;
a third semiconductor region of a second conductivity type between, in the first direction, the anode electrode and the second semiconductor region, the third semiconductor region being directly adjacent in at least the first direction to the second semiconductor region; and
a fourth semiconductor region between the first semiconductor region and a portion of the third semiconductor region, the fourth semiconductor region being directly adjacent to the third semiconductor region in at least the second direction.

18. The semiconductor device according to claim 17, further comprising:
a fifth semiconductor region of the second conductivity type directly adjacent to fourth semiconductor region in at least the second direction.

19. The semiconductor device according to claim 17, wherein the fourth semiconductor region is closer in the first direction to the cathode electrode than is the second semiconductor region.

20. The semiconductor device according to claim 17, wherein a portion of the first semiconductor region is between the second semiconductor region and the cathode electrode.
